(19) United States
(12) Patent Application Publication
(10) Pub. No.: US 2003/0178616 A1
(43) Pub. Date: Sep. 25, 2003

(54) Cavity QED devices

(76) Inventor: Thomas V. Prevenslik, Youngwood, PA (US)

Correspondence Address: Thomas V. Prevenslik, PO Box 515, Youngwood, PA, 15697, US

(21) Appl. No.: 10/179,641

(22) Filed: Jun. 25, 2002

Related U.S. Application Data
(60) Provisional application No. 60/366,855, filed on Mar. 25, 2002.

(51) Int. Cl. H01L 29/06; H01L 31/0328; H01L 31/0336; H01L 31/072; H01L 31/109

(52) U.S. Cl. 257/14

(57) ABSTRACT

QED devices emitting EM radiation are disclosed comprising structures in microscopic cavities. Steady EM radiation is produced from structures essentially permanently separated from the cavity walls, while transient EM radiation occurs by providing means to cause the temporary separation of the structures from the cavity walls. At ambient temperature, the EM radiation from atoms in structures not separated from the cavity walls is emitted at IR frequencies. However, the IR radiation is suppressed from atoms in structures separated from the cavity walls because the cavities have higher EM resonant frequencies. To conserve EM energy, the suppressed IR radiation from the structures is spontaneously emitted and combines at the QED cavity surfaces to collectively produce VUV light, the process called cavity QED induced VUV light. QED devices are disclosed utilizing cavity QED induced VUV light to excite the atoms and molecules on the cavity surfaces to produce VIS light, electrons, and ions.

### CROSS-REFERENCE TO RELATED APPLICATIONS

Pursuant to 35 USC §119(e), the timely filing of this non-provisional patent application claims the benefit of provisional patent:

Application No. 60/366,855

Filing Date: Nov. 26, 2001

Applicant: Thomas V. Prevenslik

Title of Invention: Cavity QED induced photoelectric effect

### FEDERALLY SPONSORED RESEARCH OR DEVELOPMENT

Not Applicable.

### COMPACT DISK REFERENCES

Not Applicable.

### SUMMARY

Quantum electrodynamics (QED) devices are disclosed that spontaneously emit electromagnetic (EM) radiation, and specifically infrared (IR) radiation at ambient temperature from structures within microscopic cavities, the IR radiation combining to produce vacuum ultra violet (VUV) light at the cavity surfaces, the process called cavity QED induced VUV light. QED devices are disclosed that utilize the VUV light to excite cavity surfaces to produce electrons, ions, and visible (VIS) photons. The QED devices include:

(1) Ultrasonic VIS Lamp

(2) Microsphere Light Source

(3) Thermal Laser and Thermoelectric Battery

(4) Particle Filter

The preceding QED devices are illustrative examples, and do not in any way limit the generality of cavity QED induced VUV light. The disclosure will permit those skilled in the art to devise many other QED devices utilizing cavity QED induced VUV light.

### BACKGROUND OF THE INVENTION

1. Field of the Invention

The present invention is related to the field of QED devices emitting EM radiation. Specifically, the invention relates to the field of QED devices that induce the spontaneous emission of IR radiation from atoms in structures within microscopic cavities, the IR radiation finding origin in the thermal kT energy of the atoms at ambient temperature.

2. Related Art and Present Invention

Related art to the present invention may be summarized in terms of unexplained observations of VIS photons, electrons, and ions in diverse physical phenomena. These phenomena are commonly regarded as mysterious because they do not occur at high temperature or in the presence of external sources of EM energy where they are readily explained, but rather occur at ambient temperature absent external sources of EM energy. Heretofore, explanations have been proposed to explain these phenomena, but have never included cavity QED induced VUV light. Alternatively, the present invention is the first disclosure that cavity QED induced VUV light is the common source of EM energy in these diverse phenomena by which VIS photons, electrons, and ions are produced.

### DESCRIPTION OF RELATED ART

Diverse physical phenomena producing VIS photons, electrons, and ions at ambient temperature in related art include sonoluminescence, triboluminescence, flow electrification, static electricity, and atmospheric electricity.

In the drawings:

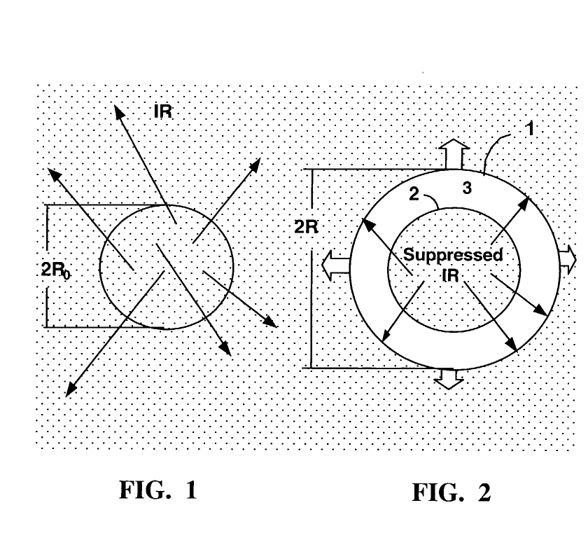

FIGS. 1 and 2 are an illustration of the QED process of cavity QED induced VUV light operating in the nucleation of bubbles during the acoustic cavitation of liquid water, known in the prior art as sonoluminescence, heretofore an unexplained phenomenon;

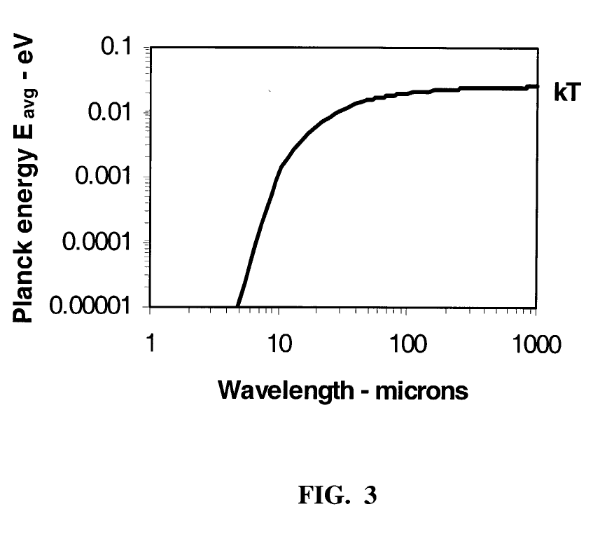

FIG. 3 is a graph showing the average Planck energy E_{avg} of an atom represented by a harmonic oscillator as a function of the wavelength λ of thermal kT energy at an ambient temperature of 300 K;

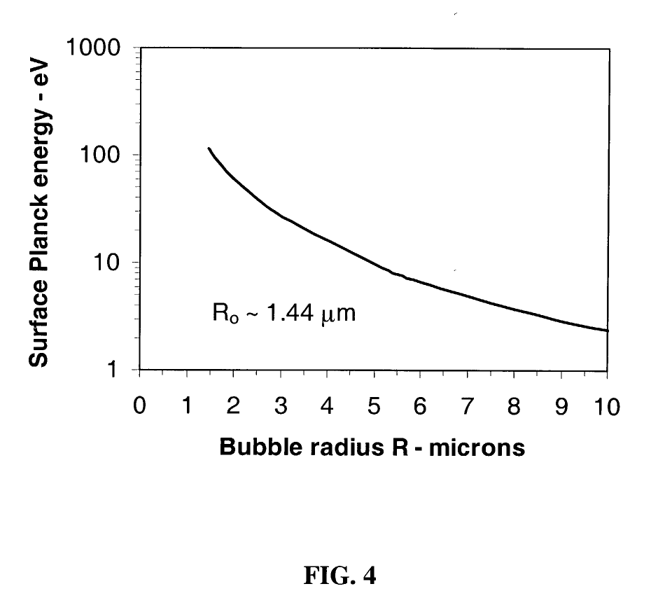

FIG. 4 is a graph illustrating the Planck energy produced by cavity QED induced VUV light on the surface of the bubble wall of radius R from sonoluminescence in water;

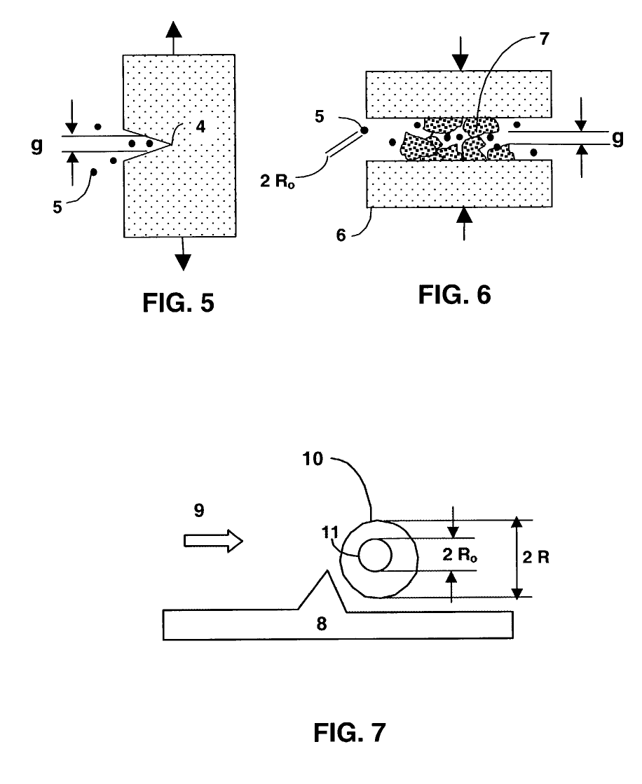

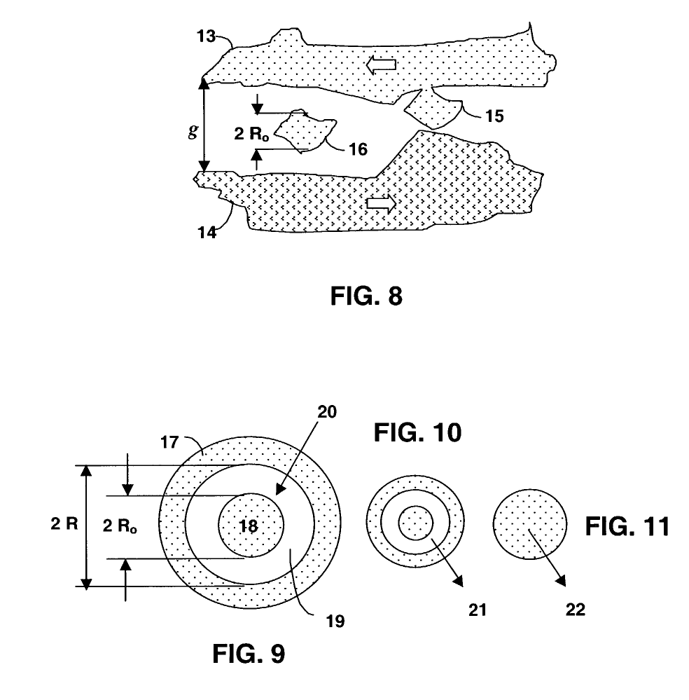

FIGS. 5-11 illustrate how other physical phenomena in the related art may be explained by the cavity QED induced VUV light disclosed in the present invention. One such phenomenon is triboluminescence. FIGS. 5 and 6 depict the emission of electrons and VIS light from the fracture and crushing of solids. FIG. 7 depicts QED induced VUV light at play in flow electrification, known in prior art by the electrical charge buildup in jet fuel and automobile gasoline. FIG. 8 shows the VUV light producing electrons in static electricity that has been unexplained since the early Greeks. FIGS. 9-11 illustrate stages in the QED induced VUV light process that produces the electrical charge in atmospheric electricity. It will become readily apparent to those versed in the art that the finding of QED induced VUV light is a discovery of fundamental importance in physics.

Sonoluminescence

Sonoluminescence is the production of coherent VIS light during the acoustic cavitation of water. Currently, sonoluminescence is thought produced by high temperatures caused by compression heating of bubble gases during collapse. However, except for traces of air and other non-condensable gases, the bubble gases are condensable water vapor. Water vapor in 2-phase equilibrium with the bubble walls maintains ambient temperature and vapor pressure as the bubble volume vanishes. Thus, high temperatures in bubble collapse do not occur and some mechanism other than high temperatures is necessary to explain sonoluminescence. The present invention produces sonoluminescence by cavity QED induced VUV light at ambient temperature. Sonoluminescence is prior art and not patentable, but QED devices that rely on cavity QED induced VUV light to produce VIS light are novel and patentable.

FIGS. 1 and 2 illustrate how cavity QED induced VUV light produces sonoluminescence. FIG. 1 shows liquid water in a state of hydrostatic compression at ambient pressure P. A hypothetical spherical volume of radius Ro is depicted. At ambient temperature T, all water molecules in the continuum emit IR radiation having a long wavelength compared to the size of the hypothetical volume. If the liquid continuum is perturbed to produce a state of hydrostatic tension, a bubble nucleates as shown in FIG. 2. Because of surface tension S, the size of the bubble can not be less than a prescribed limit. Hence, the expanding liquid bubble wall 1 of radius R separates from a tightly bound spherical particle 2 of water molecules at liquid density, the particle depicted by the hypothetical radius R₀=2S/P. For water having a surface tension S of 0.072 N/m at atmospheric pressure, R₀˜1.44 microns. The formation of the spherical particle is almost instantaneous and produces an annular gap 3 between the surfaces of the particle and bubble wall.

Prior to nucleation, the water molecules in the liquid continuum under hydrostatic compression emit N_{dof}×½ kT of EM radiation, where k is Boltzman's constant, T is the absolute temperature, and N_{dof} is the number of degrees of freedom. For water, N_{dof}=6. At ambient temperature, the EM radiation is emitted from the continuum at IR frequencies. But at the instant the particle separates from the bubble wall, the bubble is a 3-dimensional QED cavity having a high EM resonant frequency that suppresses the low frequency IR radiation from the water molecules in the particle.

Generally, suppressed radiation by cavity QED occurs as the frequency of the radiation emitted from the atoms within a cavity is lower than the EM resonant frequency of the cavity (for example, see Harouche and Raimond, “Cavity quantum electrodynamics”, Scientific American, 1993, pp. 54-62). Simply stated, the only EM radiation that can stand in the bubble is required to have a half wavelength ½ λ less than the bubble diameter 2R, where, R is the bubble radius. Thus, the resonant wavelength λ_{c} is, λ_{c}=4R. Conversely, EM radiation is suppressed for λ>λ_{c}. However, the bubble surface is required to be highly reflective to achieve the optical quality for suppressing IR radiation by cavity QED. Water is opaque (and highly reflective) at IR wavelengths λ>3 microns. But this condition is nicely satisfied in sonoluminescence, as the bubble nucleates at a radius R˜R₀ having a resonant IR wavelength λ₀=4 R₀˜6 microns where water is highly reflective.

The amount of thermal kT energy suppressed at ambient temperature is given by the harmonic oscillator and depends on the wavelength λ of the IR radiation. FIG. 3 shows the average Planck energy E_{avg} at ambient temperature to only be significant at IR wavelengths λ >10 microns, saturation occurring at kT˜0.025 eV for λ>100 μm. About 4% of the available thermal kT energy is contained at λ<10 microns, and therefore if the particle radius R₀<¼λ˜2.5 microns at the instant of separation, the IR radiation suppressed is greater than 96% of the available thermal kT energy.

Provided the spherical particle of water molecules has a radius R₀<2.5 microns, the suppressed IR energy U_{IR} is,

$${U}_{IR} < \frac{4 π}{3} {R}_{0}^{3} Ψ \qquad ( 1 )$$

where, Ψ is the EM energy density, Ψ˜N_{dof}×½ kT/Δ³ and Δ is the spacing between water molecules at liquid density, Δ˜3.1 angstroms.

Suppressed IR radiation is a loss of EM energy that is conserved by the spontaneous emission of IR radiation, the spontaneous emission absorbed by the bubble surface because of its high optical quality provided by the water molecule at IR frequencies. But the annular gap is resonant at VUV frequencies, and therefore the Planck energy in the gap increases with frequency from the IR to the VUV. The Planck energy in the gap is reduced because of the leakage of photons in the VIS, but does not detract from the production of VUV light. In this way, sonoluminescence produces VUV light in the annular gap from the cavity QED induced spontaneous emission of IR radiation at ambient temperature.

During spontaneous emission, the IR energy accumulates as multi-IR photon energy at the cavity radius R. If all the available EM energy U_{IR} suppressed during nucleation is conserved with the Planck energy E of the surface molecules at bubble radius R,

$$E = \frac{{N}_{dof}}{6} {( \frac{{R}_{0}}{R} )}^{2} ( \frac{{R}_{0}}{Δ} ) kT \qquad ( 2 )$$

At T˜300 K and a particle radius R₀˜1.44 microns, the Planck energy E accumulated by multi-IR photons at radius R˜R₎ is about 120 eV and decreases with increasing radius as shown in FIG. 4.

In sonoluminescence, the coherent VIS light observed from bubbles in water is generally not thought produced by photoluminescence of the water by VUV radiation, but rather as Ar*OH excimers decompose in the high pressures developed in bubble collapse. In cavity QED induced sonoluminescence, the excited OH states necessary to form the Ar*OH excimers are produced following the dissociation of water molecules in the annular gap into hydronium H₃O⁺ and hydroxyl OH⁻ions by cavity QED induced VUV light.

The multi-IR photon energy at radius R may be quantified by the number N_{VUV} of VUV photons having sufficient Planck energy E_{VUV} to dissociate the water molecule and raise the hydroxyl ion to excited *OH states,

$${N}_{VUV} = \frac{{U}_{IR}}{{E}_{VUV}} = \frac{2 π}{3} {{N}_{dof} ( \frac{{R}_{o}}{Δ} )}^{3} ( \frac{kT}{{E}_{VUV}} ) \qquad ( 3 )$$

where, E_{VUV}=N_{IR} kT and N_{IR} is the number of multi-IR photons. The number N_{OH} of OH ions formed from the cavity wall depends on the hydroxyl yield γ_{OH} by,

N_{OH}=γ_{OH}N_{VUV} (4)

At VUV frequencies, the yield γₚ is unity. Taking the dissociation of water to occur at E_{VUV}˜4.9 eV and a particle radius R₀˜1.44 microns, the number of ions N_{OH}˜6.6×10⁹.

Argon dissolved in the water combines with the excited hydroxyl states to form the Ar*OH excimers by the mole fraction solubility φ˜2.75×10⁻⁵. Hence, the number N_{Ar*OH} of Ar*OH excimers is, N_{Ar*OH}>φN_{OH}˜1.8×10⁵. In bubble collapse, high pressures develop in the collision of the bubble walls, the magnitude of pressure proportional to the size of the bubble prior to collapse, e.g., a bubble radius of about 35 microns develops a collapse pressure of about 200 bars. At this pressure, argon excimers decompose giving one VIS photon per excimer, or 1.8×10⁵ VIS photons. This is consistent with the experimental standard unit of sonoluminescence, i.e., the 2×10⁵ VIS photons found for the collapse of a typical bubble in air saturated water.

Cavity QED induced sonoluminescence is optimal for liquid water. Weak sonoluminescence is observed from liquid helium and nitrogen as low surface tension limits the size of the particle at nucleation that controls the number of atoms that spontaneously emit thermal kT energy, but also because of the low thermal kT energy at cryogenic temperatures. Water is the optimum liquid for the QED device because water has a high surface tension while still providing significant thermal kT energy even at ambient temperature.

Triboluminescence

Unlike sonoluminescence that occurs in the liquid state, electrons and VIS light in triboluminescence is emitted from materials as they fracture under tension or crush under compression. Triboluminescence is known from the prior art and is not patentable, but the QED process of cavity QED induced VUV light to produce triboluminescence is novel and patentable.

Triboluminescence by fracture under tension of a material by crack growth as the opening of gap g between fragments is depicted in FIG. 5. Cracks open during periods the crack tip is subjected to hydrostatic tension, the crack growth process providing a flow of microscopic particles 4 from the crack tip 5, the particles 4 comprising atoms and molecules at solid density. FIG. 6 depicts platens 6 crushing material 7. Crushing acts to close cracks to microscopic dimensions, the crushing process reducing fragments to particle sizes comparable to the dimensions of the space between platens.

Fracture and crushing as QED processes treat the microscopic gaps between fragments as 1-dimensional QED cavities having a EM resonant wavelength λ_{c}˜2 g, where g is the gap dimension in FIGS. 5 and 6. QED processes in triboluminescence produce EM energy from the spontaneous emission of IR radiation at the instant the particles separate from the fragments in fracture, or as the fragments close on the particles during crushing.

Prior to fracture or crushing, atoms and molecules in the solid state emit N_{dof}×½ kT of EM radiation. For most solid state materials, N_{dof}˜3. Similar to the liquid state, the EM radiation from the continuum in the solid state is emitted as IR radiation at ambient temperature as shown in FIG. 3.

Since the space in the gap g between crack and fragment faces has a high EM resonant frequency, the low frequency IR radiation from the atoms in the separated particle is momentarily suppressed. Suppressed IR radiation is a loss of EM energy that must be conserved, and therefore the EM energy is spontaneously emitted as multi-IR photons that accumulate to VUV levels in the atoms and molecules of fragment surfaces. For a particle of radius R₀, the Planck energy E at a distance X from the center of the particle,

$$E = \frac{1}{2} {( \frac{{R}_{0}}{X} )}^{2} ( \frac{{R}_{0}}{Δ} ) kT \qquad ( 5 )$$

Taking R₀˜1 micron and Δ˜3 angstroms, the Planck energy E at the particle surface is about 40 eV. The number N_{VIS} of VIS photons produced depends on the photoluminescence yield γₚₗ and the number of N_{VUV} of VUV photons,

N_{VIS}=γₚₗN_{VUV} (6)

In triboluminescence, the VIS light observed from fracture of the solid state is the result of the cavity QED induced VUV light, the VIS light produced from the excitation of gases in the crack and by the photoluminescence of the solid state materials forming the crack surfaces.

Flow Electrification

In the flow of jet fuels and automobile gasoline, the fuel is electrified posing a danger caused by discharge of the charge buildup. Flow electrification is known from the prior art and is not patentable, but the QED process of cavity QED induced VUV light to produce flow electrification is novel and patentable.

FIG. 7 illustrates the QED induced flow electrification. Protrusions 8 in the pipe wall perturb the flow 9 to cause low-pressure regions. In QED induced flow electrification, the QED cavities are microscopic bubbles 10 that nucleate in the low-pressure regions. Because of surface tension, the nucleation produces a spherical particle 11 of fuel molecules at liquid density. Fluids that electrify including aviation fuel and automobile gasoline are insulators having low electrical conductivity, thereby permitting the buildup of electrical charge. In contrast, water has an electrical conductivity about 7 orders of magnitude greater than fuels, i.e., charge buildup does not occur in water during acoustic cavitation. In the flow of insulator fuels, cavity QED induced VUV light charges the fluid positive by the liberation of electrons by the photoelectric effect.

Prior to nucleation, the fluid molecules in the liquid continuum under hydrostatic compression emit N_{dof}×½ kT of EM radiation, which at ambient temperature is emitted from the continuum as IR radiation. For fuels, N_{dof}˜6. But at the instant the particle separates from the bubble, the low frequency IR radiation from the fluid molecules in the particle is suppressed as the bubble has a high EM resonant frequency. Suppressed IR radiation is a loss of EM energy that is conserved by the spontaneous emission of IR radiation that accumulates to VUV levels on the bubble surface. For a particle of radius R₀, the Planck energy E on the bubble wall at a distance R from the center of the particle,

$$E = {( \frac{{R}_{0}}{R} )}^{2} ( \frac{{R}_{0}}{Δ} ) kT \qquad ( 7 )$$

where, the particle radius R₀˜2S/P. For fuels, S˜0.02 N/m. At atmospheric pressure, R₀˜0.4 microns. For n-Heptane having a molecular weight of 100 and density 684 kg/m³,Δ˜6.2 angstroms, the Planck energy E at the particle surface is about 16 eV.

The number Nₑ of electrons produced by a single bubble from the VUV irradiation of the bubble wall depends on the electron yield γₑ by,

Nₑ=γₑN_{VUV} (8)

where, the number of VUV photons N_{VUV}˜1.77×10⁷ from Eqn. (3). For γₑ>0.0001, Nₑ>2000 with an equivalent number of charged molecular states in the fluid.

In flow electrification, the charged fluid and electrons are the result of the cavity QED induced photoelectric effect, the electrons produced by the VUV irradiation of the bubble wall at the instant of bubble nucleation.

Static Electricity

Since the time of the early Greeks, static electricity is a well-known phenomenon in the prior art and not patentable, but the QED process of cavity QED induced VUV light to produce static electricity is novel and patentable.

FIG. 8 illustrates the cavity QED induced static electricity. Microscopic gaps g that open and close as materials 13 and 14 are made to contact each other are 1-dimensional QED cavities. Particles 15 that are part of material 13 rub off to produce free particle 16 in the gap, although the free particle 16 may be present in the surroundings as the QED cavity opens or closes. Otherwise, QED induced static electricity process and triboluminescence are similar.

Prior to confinement in the QED cavity, the atoms in the particles have N_{dof}×½ kT of EM energy, which at ambient temperature is emitted as IR radiation. But at the instant the 1-D cavities open or close to an EM resonant wavelength λ_{c}<10 microns, or gap g <5 microns, the low frequency IR radiation from the water molecules in the particle is suppressed. To conserve EM energy, the suppressed IR radiation is spontaneously emitted and accumulates to VUV levels on the adjacent material surfaces.

In cavity QED induced static electricity, the VUV radiation produces electrons from the contacting materials by the photoelectric effect. The number Nₑ of electrons produced from the VUV irradiation of the particles depends on the electron yield γₑ of the materials [see Eqn. (6)] and the number Nᵥᵤᵥ of VUV photons [see Eqn.(3)]. For dissimilar materials irradiated with VUV light, both materials lose electrons. But the material with the highest electron yield per VUV photon loses more electrons than it gains and charges positive, the one gaining a net number of electrons is charged negative.

Atmospheric Electricity

In atmospheric electricity, storms producing lightning and thunder are well-known from the prior art and not patentable, but the QED process of cavity QED induced VUV light to produce atmospheric electricity is novel and patentable.

FIGS. 9-11 illustrate cavity QED induced atmospheric electricity. FIG. 9 shows a microscopic bubble 17 nucleates around a central particle 18 during the large volume expansion in graupel, the graupel a liquid-ice mixture that forms as moisture carried by updrafts of the storm supercools at high altitudes. Bubble nucleation produces VUV light by cavity QED induced spontaneous emission that dissociates the water molecules in the annular gap 19 between the particle and bubble surfaces into hydronium and hydroxyl ions. Unlike sonoluminescence where little air is drawn into the expanding bubble because of the short time available at acoustic frequencies, graupel expansion is prolonged allowing air 20 to be drawn into the bubbles.

Ionic charge separation occurs by the pH of the raindrops. Typically, rainwater has an acid pH, and therefore the bubble particle and walls carry a positive background charge. The cavity QED produced hydronium ions are repulsed to the bubble vapor while the companion hydroxyl ions are attracted to the surfaces of the particle and the bubble wall.

The hydronium and hydroxyl ions react with water and nitrogen molecules to form positive charge proton-hydrate (PH) and negative charge non-proton-hydrate (NPH) clusters.

The graupel volume contracts to collapse the bubbles as depicted in FIG. 10. But the water vapor is not compressed because it is a condensable vapor in 2-phase equilibrium with the liquid bubble walls. Only the air drawn into the graupel after nucleation is compressed to a high pressure. Hence, air with PH vapor 21 is forced out of the graupel, the vapor promptly forming positive charged micro-droplets; whereas, the NPH ions are attracted to the graupel.

FIG. 11 shows the graupel later falling to the earth, the NPH ions subliming as a negative charged vapor. Charge separation that began at bubble nucleation is completed by the formation of light PH cluster clouds that remain buoyant in the stratosphere while the heavier NPH clouds fall to the earth.

In cavity QED induced atmospheric electricity, cloud-to-ground lightning is caused by the discharge of negative charge NPH clouds with the positive charge earth; whereas, cloud-to-cloud lightning is caused by discharge between the negative charged NPH clouds and positive charge PH clouds.

### DESCRIPTION OF THE INVENTION

The present invention is described by QED devices that rely on the cavity QED induced VUV light to produce VIS photons, electrons, and ions.

In the drawings:

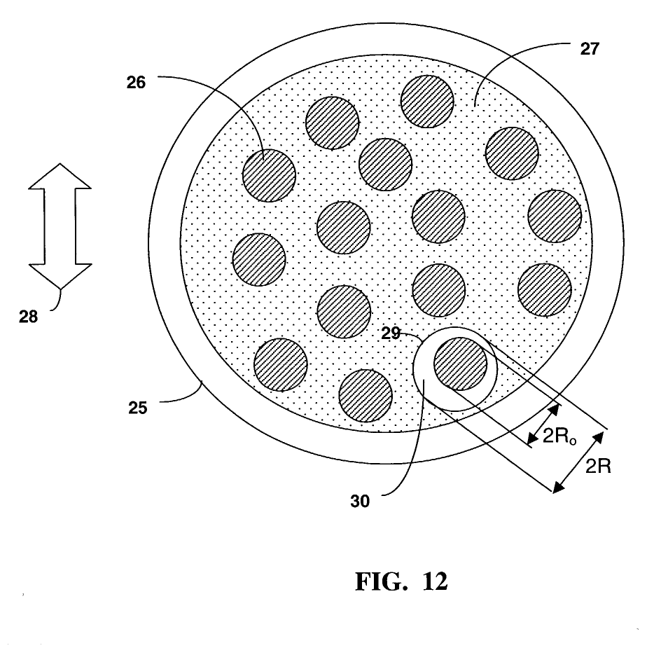

FIG. 12 is a cross-section elevation view of a preferred embodiment of the present invention for a QED device comprising an ultrasonic lamp producing VIS light.

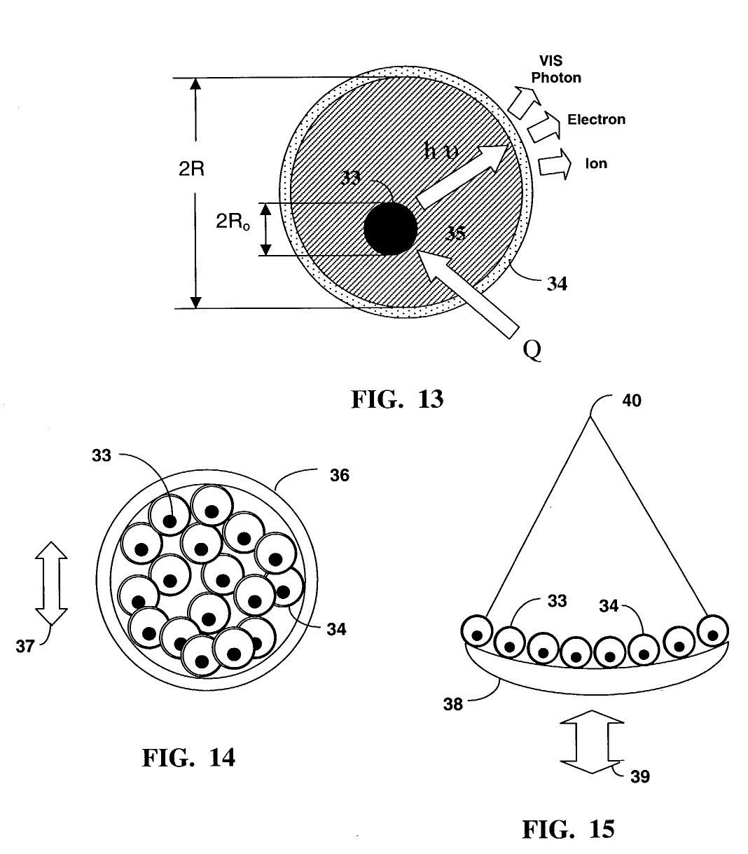

FIG. 13 is a cross-section elevation view depicting another preferred embodiment of the present invention for QED devices comprising a solid particle encapsulated in a microsphere to produce VIS photons, electrons, and ions. FIG. 14 shows how the microsphere light sources may be arranged in a small container to produce VIS light by manual shaking. FIG. 15 shows how the light sources may be placed on acoustically driven optical elements.

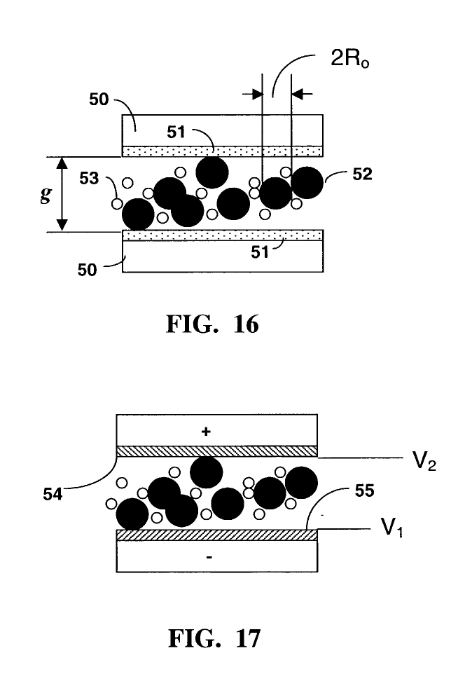

FIG. 16 shows the present invention in a cross-section elevation view for still another preferred embodiment for a QED device to produce VIS photons and electrons comprising layered optical windows utilizing thermal energy from the surroundings to drive a QED thermal laser. A similar layered configuration for a QED device of a thermoelectric battery is shown in FIG. 17.

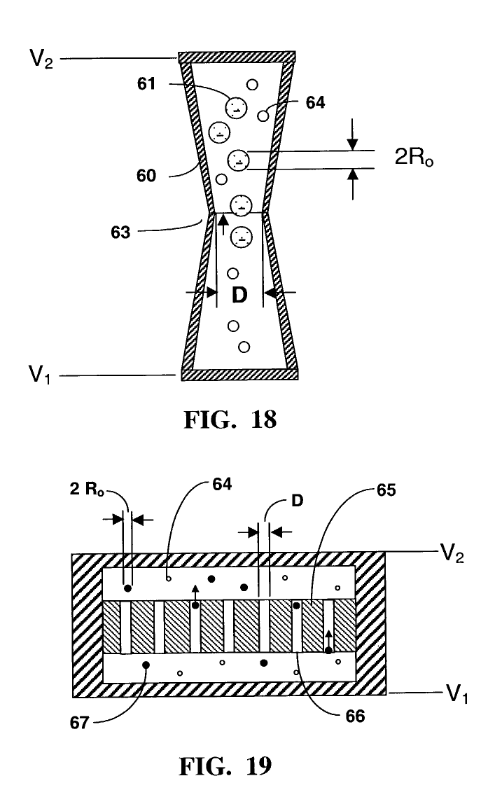

FIG. 18 and 19 depict the present invention in a cross-section elevation view of a QED device as a particle filter. FIG. 18 shows a microscopic cell producing VIS light. A particle filter producing comprising a plurality of microscopic cells is shown in FIG. 19.

The foregoing are given only as illustrative examples of the use of cavity QED induced VUV light in QED devices disclosed in the present invention, and do not in any way limit the generality of QED devices embodied in the present invention.

Ultrasonic Lamp and Battery

In one preferred embodiment, cavity QED induced VUV light is used in a QED device to produce VIS light in an ultrasonic lamp.

FIG. 12 illustrates the cavity QED induced ultrasonic VIS lamp. A transparent container 25 houses a large number of microscopic solid particles 26 in liquid water 27. The particles are essentially spherical and fabricated from a metal oxide, such as zinc oxide or the like having a high photoluminescence yield of VIS photons at VUV frequencies. Acoustic crystals 28 the container in orthogonal directions to immerse the particles 26 in a spherical acoustic field.

During periods of hydrostatic tension in the acoustic cycle, the bubbles 29 having a radius R nucleate in the liquid around the solid particles of radius R₀. In contrast, the particle in sonoluminescence is comprised solely of water molecules at liquid density formed by surface tension. Metal oxides are hydrophobic in water, and therefore the nucleation process in the ultrasonic lamp exposes a dry surface. An annular gap 30 promptly forms between the particle and bubble wall surfaces, providing the particle radius Rₒ is slightly less than the surface tension radius for water, i.e., R₀<2S/P˜1.44 microns. Hence, particles 26 are required to have a diameter radius 2R₀<2.88 microns.

Prior to nucleation, the metal oxide molecules in the particle emit N_{dof}×½ kT of EM radiation. At ambient temperature, EM radiation is emitted from the particle as IR radiation. But at the instant the bubble wall separates from the particle, the bubble having a high EM resonant frequency suppresses the low frequency IR radiation from the metal oxide molecules in the particle. Suppressed IR radiation is a loss of EM energy that is conserved by the spontaneous emission of IR radiation. Hence, the IR photons are absorbed [see Eqn. 3] because of the high optical quality of the QED cavity provided by the absorption of the water molecule at IR frequencies. Subsequently, the VUV resonance of the annular gap [see Eqn. 6] excites the surface of the particles at VUV frequencies.

In the cavity QED acoustic lamp, VIS light is produced by photoluminescence of the metal oxide particles by the cavity QED induced VUV light from the spontaneous emission of IR radiation.

The QED acoustic lamp may be converted to a QED acoustic battery by replacing the water 27 with liquid n-Heptane having a low electrical conductivity, the electrons produced from the n-Heptane from the cavity QED induced VUV light by photoelectric effect.

Microsphere Light Source

In another preferred embodiment, cavity QED induced VUV light is used in a microsphere light source.

FIG. 13 shows the solid particle 33 of radius R₀ encapsulated by an IR transparent solid 35 within a shell 34 having radius R. Both particle 33 and shell 34 are fabricated from zinc oxide having high photoluminescence yield. The particle 33 is encapsulated in silicon 35 that is transparent in the IR from about 1 to 20 microns.

In macroscopic cavities absent cavity QED effects, the particle 33 gains and loses heat Q the usual way by conduction with the shell 34 as shown in FIG. 7(a). However, cavity QED effects modify the heat transfer by including the rapid loss of thermal kT energy by spontaneous emission of EM radiation hυ compared to the slow heat Q loss by conduction. Heat Q gained by the particle by conduction is promptly lost by the spontaneous emission of EM radiation hυ. The QED device finds application as a steady QED laser or thermoelectric device driven by the temperature of the surroundings.

Microspheres fabricated with the particles 33 in a vacuum without a solid IR transparent material 35 are depicted to be vibrated in FIG. 14 and 15. A vacuum requires intermittent contact to transfer heat from the shell 34 to the particle 33. FIG. 14 shows microspheres in a transparent container 36 vibrated manually by hand 37 to produce VIS light. FIG. 15 shows a concave optical lens 38 coated with a microsphere layer excited by an acoustic drive 39 to produce a beam of VIS light focussed at point 40.

Provided the gap between the particle 33 and the shell 34 is IR transparent, the shells 34 are prescribed to have a radius R <2.5 microns, or a wavelength λ<10 microns consistent with the suppression of IR radiation at ambient temperature as shown in FIG. 2. Suppressed IR radiation is spontaneously emitted by cavity QED provided the particle is separate from the microsphere.

For a silicon 35 encapsulated particle 33, the QED induced VUV light produces a number of VUV photons [see Eqn. 3] that are converted to VIS light [see Eqn. 6] by photoluminescence, e.g., for a microsphere of zinc oxide, a VIS green light is produced. In the alternative particle 33 encapsulated in an evacuated shell 34 provided with a filler gas, the VUV light excites the filler gas, which if nitrogen produces blue VIS light.

Thermal Laser and Thermoelectric Battery

In still another preferred embodiment, cavity QED induced VUV light is used to provide a steady QED thermal laser and thermoelectric battery.

The VIS laser shown in FIG. 16 comprises optical quartz windows 50 about 1 cm in diameter separated to form a 1-dimensional QED cavity having a gap g of about 5 microns, thereby providing the suppression of IR radiation at wavelength λ>2 g˜10 microns. The interior window surfaces 51 are coated with metal oxide, such as zinc oxide or the like having a high photoluminescence yield of VIS photons at VUV frequencies. A zinc oxide powder 52 having a diameter 2R₀<3 microns is provided in the gap. The QED cavity carries a filler gas 53, such as nitrogen.

FIG. 17 depicts the cavity QED thermoelectric battery that except for the window coating materials is otherwise identical to the QED thermal laser shown in FIG. 8(a). The QED thermoelectric battery requires one coating 54 to have a high photoelectric yield while the other 55 is reflective at VUV frequencies to optimize the potential difference and electron yield between the materials.

In both QED laser and thermoelectric battery, thermal energy from the surroundings is converted to a continuous steady low-level source of VIS light or electrons. Heat is transferred by convection from the windows 50 to the powder 52 by collisions of the filler gas molecules with to maintain the zinc oxide powder 52 at ambient temperature, the heat compensating for the loss of IR radiation by spontaneous emission induced by cavity QED.

In the QED thermal laser, the powder atoms spontaneously convert thermal kT energy to VUV light [see Eqn. 3]. The QED thermal laser produces VIS light from the metal oxide coated windows, e.g., zinc oxide produces a green light by photoluminescence [sse Eqn. 6]. In the alternative, the VUV light excites the filler gas, e.g., nitrogen produces blue VIS light.

The QED thermoelectric battery converts the thermal energy of the surroundings to a potential difference V₂−V₁ and a source of electrons. The cavity QED induced VUV light produces electrons [see Eqn. 7] from both materials 54 and 55 depending on their photoelectric yields, the material with the higher yield losing more electrons and acquires a positive charge [see Eqn. 8]. Material 54 is depicted to acquire a positive charge owing to its higher electron yield, while the reflective material 55 gains electrons and charges negative.

Particle Filter

In a still another preferred embodiment, the QED device is used in a filter having microscopic pores resonant with the flow of solid spherical particles to provide a source of VIS photons and electrons.

FIG. 18 illustrates a microscopic QED flow cell. Solid particles 61 of n-type semiconductor material having a diameter 2R₀<3 microns move in tube 62 through a restriction 63 under the influence of an external electric field produced by voltages V₁ and V₂. The particles 61 carry a negative charge and the tube 62 is fabricated from an electrical insulator material. VUV light is produced as the particles move through the restriction 63 having a dimension D with an EM resonance that suppresses IR radiation. The channel is evacuated and filled to a low-density nitrogen gas 64. At ambient temperature, IR radiation is suppressed at a wavelength λ of about 10 microns, or a diameter D of 5 microns.

A resonant filter comprising a plurality of microscopic pathways is illustrated in FIG. 19. The filter body 65 is an electrical insulator provided with a plurality of microscopic pathways 66 having a nominal diameter D <10 microns. Solid particles 61 of n-type semiconductor material having a spherical diameter 2R₀<3 microns move through the pathways 65 under the influence of an external electric field produced by voltages V₁ and V₂.

VIS photons are caused by the excitation of the nitrogen gas by cavity QED induced VUV light produced as the particles move through the restrictions in FIGS. 9(a) and (b). The VUV light excitation produces a positive charged insulator material from the electron loss by the photoelectric effect, the electrons lost by the insulator carried away by the electric field to a collector of the battery.

What I claimed is:

1. A QED device producing cavity QED induced VUV light comprising: structures in a microscopic cavity, said structures of essentially temporary construction, said QED device utilizing the thermal kT energy of atoms in said structures as the source of EM energy, said cavity providing a QED confinement of IR radiation from said atoms defined by the harmonic oscillator at ambient temperature T. said QED device provided with means of separating said structures from the walls of said cavity, said atoms emitting IR radiation provided said structures are not separated from said cavity walls, said IR radiation from said atoms momentarily suppressed as said structures separate from said cavity walls, said QED confinement inducing spontaneous emission of said suppressed IR radiation from said atoms, said spontaneous IR emission combining at said cavity wall to produce said cavity QED induced VUV light.

2. A plurality of QED devices as recited in claim 1.

3. The QED device as recited in claim 1, wherein material of said cavity wall is selected to enhance VIS photon yield by photoluminescence from said cavity QED induced VUV light.

4. A plurality of QED devices as recited in claim 3.

5. The QED device as recited in claim 1, wherein material of said cavity wall is selected to enhance electron yield by the photoelectric effect from said cavity QED induced VUV light.

6. A plurality of QED devices as recited in claim 5.

7. The QED device as recited in claim 1, wherein material of said cavity wall is selected to enhance ionic yield from said cavity QED induced VUV light.

8. A plurality of QED devices as recited in claim 7.

9. A QED device producing cavity QED induced VUV light comprising: structures in a microscopic cavity, said structures of essentially permanent construction, said QED device utilizing the thermal kT energy of atoms in said structures as the source of EM energy, said cavity providing a QED confinement of IR radiation from said atoms defined by the harmonic oscillator at ambient temperature T, said QED confinement inducing spontaneous emission of IR radiation from said atoms in said structures, said spontaneous emission of IR radiation reducing said thermal kT energy of said atoms, said reduction in said thermal kT energy compensated by convection and conduction heat flow from the thermal surroundings through cavity walls to said atoms in said structures, said spontaneous IR emission combining at said cavity walls to produce said cavity QED induced VUV light.

10. A plurality of QED devices as recited in claim 9.

11. The QED device as recited in claim 9, wherein material of said cavity wall is selected to enhance VIS photon yield by photoluminescence from said cavity QED induced VUV light.

12. A plurality of QED devices as recited in claim 11.

13. The QED devices as recited in claim 9, wherein material of said cavity wall is selected to enhance electron yield by the photoelectric effect from said cavity QED induced VUV light.

14. A plurality of QED devices as recited in claim 13.

15. The QED devices as recited in claim 9, wherein material of said cavity wall is selected to enhance the ionic yield from said cavity QED induced VUV light.

16. A plurality of QED devices as recited in claim 15.

17. A QED device of an ultrasonic VIS lamp at ambient temperature comprising: a transparent container housing a large number of microscopic solid particles in liquid water, said particles essentially spherical and fabricated from zinc oxide having a nominal diameter of about 3 microns, said housing driven by acoustic crystals in orthogonal directions, said drives immersing the particles in a spherical acoustic field, said particles producing cavity QED induced VUV light at the water interface, said cavity QED induced VUV light producing VIS photons from said particles by photoluminescence.

18. A QED device of a microsphere producing VIS light at ambient temperature comprising:
a solid particle encapsulated in a thin shell by a layer of IR transparent silicon, said particle essentially spherical having a nominal diameter of about 3 microns, said layer of silicon having a nominal thickness of about 1 micron, said particle and said shell fabricated from zinc oxide, said shell forming a spherical QED cavity having a resonant wavelength of about 10 microns, said QED cavity inducing spontaneous emission of IR radiation from atoms in said particle at ambient temperature, loss of thermal kT energy by said atoms by said spontaneous emission of said IR radiation compensated by conduction heat gain from ambient surroundings, said spontaneous emission of IR radiation combining to produce cavity QED induced VUV light at said shell, said cavity QED induced VUV light producing VIS light from said shell by photoluminescence.

19. A plurality of QED devices as recited in claim 18.

20. The QED device as recited in claim 18, wherein said thin shell is a metal or semi-conductor material selected to enhance the electron yield under said cavity QED induced VUV light, said QED device finding application as a thermoelectric battery providing a source of electrons.

21. A plurality of QED devices as recited in claim 20.

22. A QED device for a thermal laser comprising: a pair of optical quartz windows coated with zinc oxide, coated window surfaces separated by a gap of about 5 microns, said gap providing a QED cavity having a resonant wavelength of about 10 microns, said QED cavity provided with zinc oxide powder having a nominal diameter of about 3 microns, said QED confinement inducing spontaneous emission of IR radiation from atoms in said powder at ambient temperature, loss of thermal kT energy by said spontaneous emission of IR radiation from said atoms in said powder compensated by convection heat gain from the thermal surroundings, said heat converted by said spontaneous emission of IR radiation from said particles to produce cavity QED induced VUV light at said coated window surfaces, said cavity QED induced VUV light producing VIS light from said coated window surfaces by photoluminescence.

23. The QED device in claim 22, wherein one of said window pair is coated with a metal having a high electron yield, the other of said windows coated with a VUV reflective material, said cavity QED induced VUV light producing electrons by the photoelectric effect, said QED device finding application as a thermoelectric battery.

24. A QED device for a flow filter producing electrons comprising: a plurality of microscopic pathways having an nominal diameter of about 10 microns, said pathways formed in an electrical insulator material, said QED device provided with solid particles fabricated from n-type semiconductor material having a spherical diameter of about 3 microns, said QED device provided with an electric field to move said particles within said pathways, atoms in said particles emitting IR radiation before entering said pathways, said IR radiation momentarily suppressed upon entering the pathways, said suppressed IR radiation spontaneously emitted from said particles to conserve EM energy, said spontaneous IR emission accumulating in the surfaces of said pathways to produce cavity QED induced VUV light, said cavity QED induced VUV light liberating electrons by the photoelectric effect.
